(19) United States
(12) Patent Application Publication
(10) Pub. No.: US 2026/0190280 A1
(43) Pub. Date: Jul. 2, 2026

(54) LIQUID COOLING HEAD

(71) Applicant: SHENZHEN APALTEK CO., LTD., Shenzhen (CN)

(72) Inventors: Qineng XIAO, Dongguan (CN); Dagao ZHENG, Shenzhen (CN); Jun-Chun QIU, Shenzhen (CN); Zhenhong TANG, Shenzhen (CN)

(21) Appl. No.: 19/433,639

(22) Filed: Dec. 26, 2025

(30) Foreign Application Priority Data
Jan. 2, 2025 (CN) 2025200155059

(51) Int. Cl. H05K 7/20

(52) U.S. Cl. CPC H05K 7/20218

(57) ABSTRACT

A liquid cooling head includes a bottom seat, a main body, a separating plate, a first and a second sealing rings. The main body has a first liquid port, a first blind groove, a second liquid port, and a second blind groove. The separating plate is arranged between the bottom seat and the main body to form a heat exchange chamber and has a first convex block, a second convex block, a first through groove, and a second through groove. The first and second convex blocks respectively fill the first and second grooves to form a first channel and a second channel that are communicated to the heat exchange chamber through the first and second through grooves respectively. The first and second sealing rings respectively surround the separating plate and the first sealing ring. The liquid cooling head may improve sealing performance and positioning effect between the components.

### BACKGROUND

### Technical Field

The present disclosure relates to the field of liquid cooling, particularly to a liquid cooling head with good sealing performance.

### Description of Related Art

As electronic technology develops toward thinner size and higher-performance, liquid cooling has been widely used as a primary means of heat dissipation. In a liquid cooling system, the liquid cooling head is directly attached to the heat source of the electronic component to absorb the heat generated by the heat source. Therefore, initial heat dissipation is achieved by the coolant flowing through the liquid cooling head, and then the coolant further carries the heat to the radiator for secondary heat dissipation, so as to achieve good heat dissipation efficiency. For ease of manufacturing, most existing liquid cooling heads are divided into two parts—a base seat and a main body—which are then joined and fixed together by welding or screwing.

However, since the mating surface between the base seat and the main body may have narrow gaps, they cannot seal and attach tightly, such that the coolant may leak from the position between the base seat and the main body to cause damage of the electronic components. Furthermore, when the base seat and the main body of the existing liquid cooling heads are assembled, they may generate relative sliding or displacement to affect the ease of assembly.

In view of the above, the inventor seeks to overcome the aforementioned drawbacks associated with the current technology and aims to provide an effective solution through extensive researches along with utilization of academic principles and knowledge.

### SUMMARY

The primary objective of the present disclosure is to efficiently increase sealing performance of the liquid cooling head and positioning effect between the components, so as to prevent the coolant from leakage and improve the ease of assembly.

To accomplish the aforementioned objective, the present disclosure provides a liquid cooling head includes a bottom seat, a main body, a separating plate, a first sealing ring, and a second sealing. The bottom seat has a fin group. The main body is arranged on the bottom seat correspondingly to the fin group. The main body has a first liquid port, a second liquid port, a first blind groove, and a second blind groove. The first liquid port is communicated to the first blind groove. The second liquid port is communicated to the second blind groove. The separating plate is arranged between the bottom seat and the main body and covers the fin group to form a heat exchange chamber. The separating plate has a first convex block, a second convex block, a first through groove, and a second through groove. The first convex block fills a part of the first blind groove to form a first channel. The second convex block fills a part of the second blind groove to form a second channel. The heat exchange chamber is communicated to the first channel through the first through groove. The heat exchange chamber is communicated to the second channel through the second through groove. The first sealing ring is arranged between the bottom seat and the main body and surrounds the separating plate. The second sealing ring is arranged between the bottom seat and the main body and surrounds the first sealing ring.

Another aspect of the present disclosure provides that the fin group includes a plurality of cooling fins, each of the cooling fins is parallel to each other, the first through groove is perpendicular to each of the cooling fins, the second through groove is parallel to each of the cooling fins.

Another aspect of the present disclosure provides that the first through groove is correspondingly located at a center of each of the cooling fins, the second through groove is correspondingly located on a side of each of the cooling fins.

Another aspect of the present disclosure provides that the first convex block is elongated strip shape or L-shape.

Another aspect of the present disclosure provides that the main body further has an acceleration chamber, the first through groove is communicated to the first channel through the acceleration chamber.

Another aspect of the present disclosure provides that the main body further has a first annular groove and a second annular groove, at least a part of the first sealing ring is accommodated in the first annular groove, at least a part of the second sealing ring is accommodated in the second annular groove.

Another aspect of the present disclosure provides that the first liquid port is perpendicular to the first channel.

Another aspect of the present disclosure provides that the second liquid port is perpendicular to the second channel.

Another aspect of the present disclosure provides that the first liquid port and the second liquid port are located on same side of the main body.

Another aspect of the present disclosure provides that the bottom seat has an indentation, the fin group is located in the indentation, the separating plate is fixed in the indentation.

In the liquid cooling head of the present disclosure, the first sealing ring is arranged between the bottom seat and the main body and surrounds a periphery of the separating plate, the second sealing ring is arranged between the bottom seat and the main body and surrounds a periphery of the first sealing ring, so as to efficiently increase sealing performance of the liquid cooling head to prevent the coolant from leakage. In addition, the first convex block fills the part of the first blind groove to form the first channel, and the second convex block fills the part of the second blind groove to form the second channel, so as to increase positioning effect between the components and improve the ease of assembly.

### BRIEF DESCRIPTION OF THE DRAWINGS

FIG. 1 is a perspective view of the present disclosure;

FIG. 2 is an exploded view of the present disclosure;

FIG. 3 is a cross-sectional front view of the present disclosure;

FIG. 4 is a cross-sectional side view of the present disclosure; and

FIG. 5 is another perspective view of the present disclosure.

### DETAILED DESCRIPTION

It is to be understood that the terms for indicating positions and the location relation, for example “front”, “rear”, “left”, “right”, “front end”, “rear end”, “distal end”, “longitudinal direction”, “lateral direction”, “vertical direction”, “top” and “bottom”, are based on the positions and the location relation disclosed in the drawings, and only used for disclosing the present disclosure and not used for indicating or implying the specified location of the device or the components or the specified structure and operation in certain location, thus the present disclosure is not intended to be limiting.

For example, the terms of “first”, “second”, “third”, “forth” and “fifth” are used for illustrating each unit, component, area, layer and/or part. The component, the unit, the area, the layer and/or the part are not limited by the terms. These terms are only used for separating the element, the assembly, the area, the layer, or the part. Unless being clearly indicated according to the whole specification, the terms for example “the first”, “the second”, “the third”, “the fourth” and “the fifth” are not used for implying the order or sequence.

As used herein and not otherwise defined, the terms "substantially" and "approximately" are used to describe and describe small changes. When used in connection with an event or situation, the terms may include the precise moment at which the event or situation occurs, as well as the event or situation occurring to a close approximation. For example, when combined with a numerical value, the terms may include a range of variation equal to or less than ±5% of the numerical value, such as equal to or less than ±4%, equal to or less than ±3%, equal to or less than ±2%, equal to or less than ±1%, equal to or less than ±0.5%, equal to or less than ±0.1%, or equal to or less than ±0.05%.

The technical contents of the present disclosure will become apparent with the detailed description of embodiments and the accompanied drawings as follows. However, it shall be noted that the accompanied drawings are for illustrative purposes only such that they shall not be used to restrict the scope of the present disclosure.

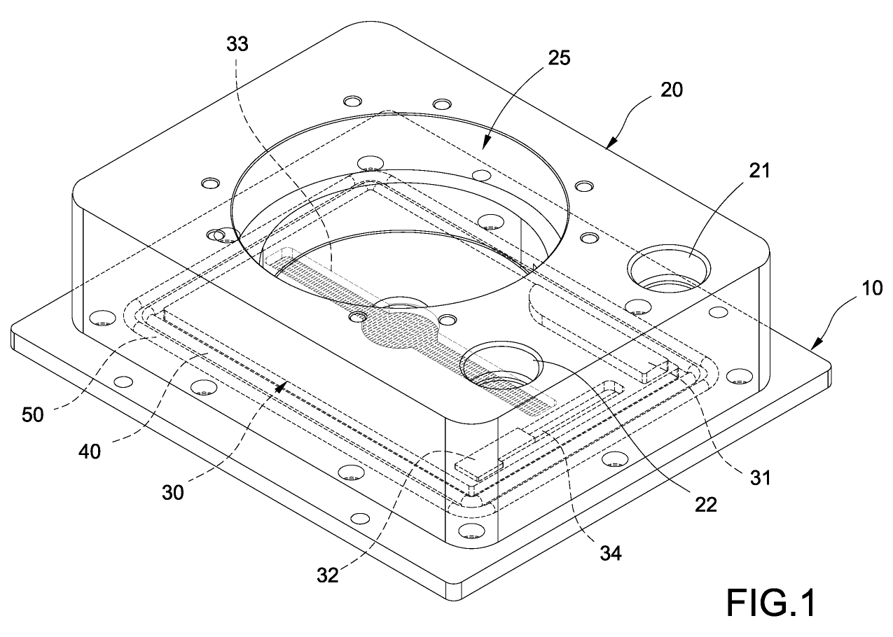

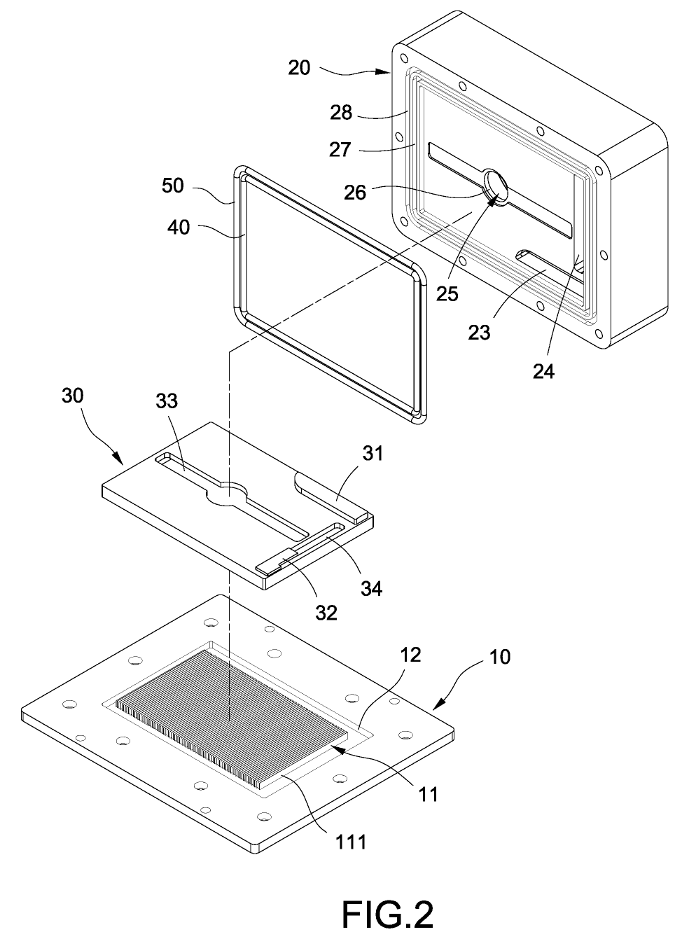

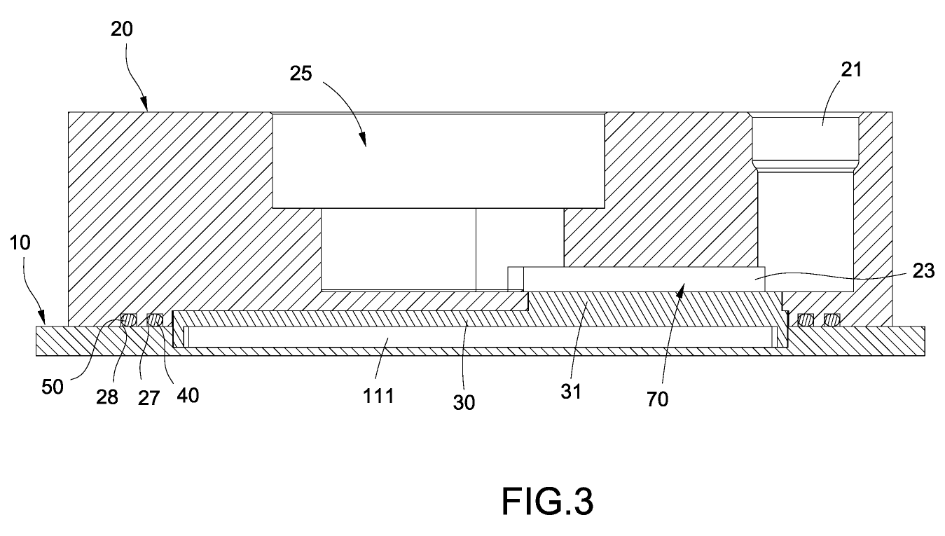

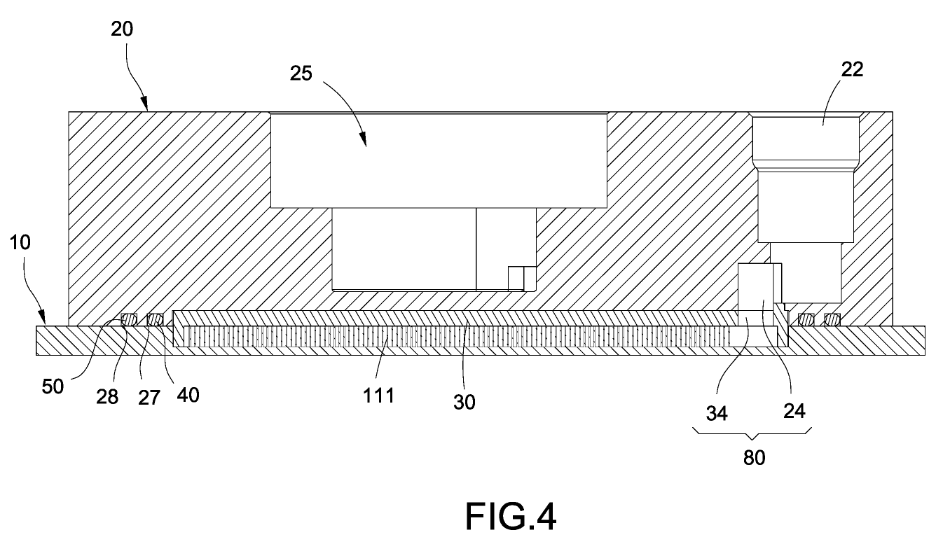

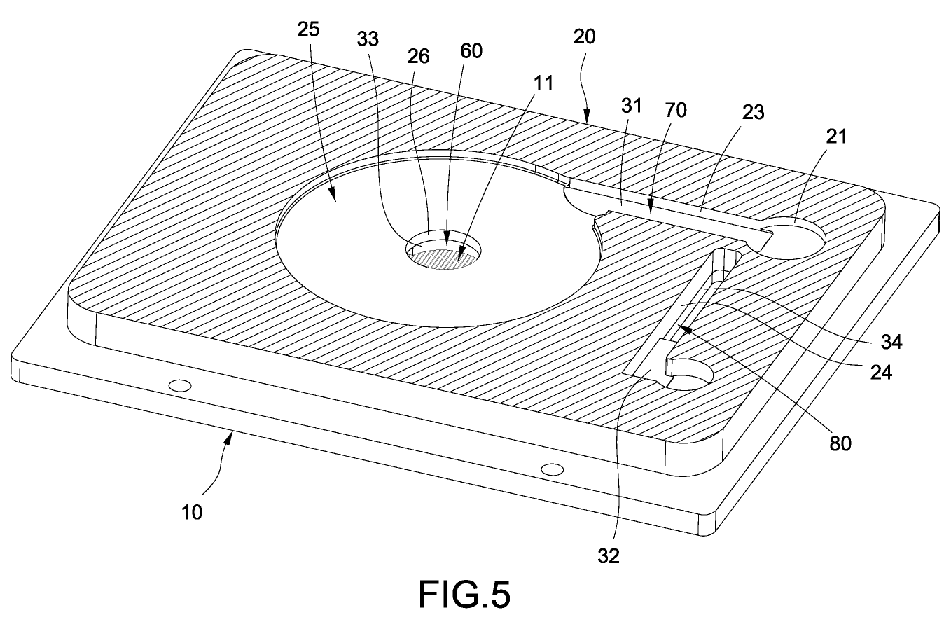

The present disclosure provides a liquid cooling head for a coolant (not labeled in figures) to flow through, so as to cool a heat source attached by the liquid cooling head. Please refer to FIG. 1, FIG. 2, FIG. 3, FIG. 4, and FIG. 5, the liquid cooling head of the present disclosure mainly includes a bottom seat 10, a main body 20, a separating plate 30, a first sealing ring 40, and a second sealing 50.

In the embodiment, the bottom seat 10 is rectangular and made of a metal material with good thermal conductivity, but the present disclosure is not limited to this embodiment. The bottom seat 10 has a fin group 11. The fin group 11 is located on a top of the bottom seat 10. The fin group 11 includes a plurality of cooling fins 111 substantially parallel to each other along a longitudinal direction, and a cooling channel (not labeled in figures) is formed between any two adjacent cooling fins 111. In the embodiment, the cooling fins 111 are arranged at intervals and are substantially parallel to one another, the cooling fins 111 are formed on the bottom seat 10 in one-piece form by casting or skived, but the present disclosure is not limited to this embodiment. In other words, the cooling fins 111 may also be fixed on the bottom seat 10 by welding, screwing, bonding, or embedding.

In the embodiment, the main body 20 is rectangular and made of a metal material with good thermal conductivity, but the present disclosure is not limited to this embodiment. The main body 20 is arranged on the bottom seat 10 correspondingly to the fin group 11. In detail, the main body 20 of the embodiment is fixed to the bottom seat 10 through a plurality of bolts (not shown in figures), but the main body 20 in other embodiments may also be fixed to the bottom seat 10 by welding or other methods. The main body 20 mainly has a first liquid port 21, a second liquid port 22, a first blind groove 23, and a second blind groove 24. Both the first liquid port 21 and the second liquid port 22 of the embodiment are located on same side of the main body 20 and located on a top of the main body 20, but the present disclosure is not limited to this embodiment. The first liquid port 21 and the second liquid port 22 may also be located on different sides of the main body 20 or both be located on a left side, a right side, a front side, or a rear side of the main body 20 according to different needs. Both the first blind groove 23 and the second blind groove 24 are located on a bottom of the main body 20. The first liquid port 21 is communicated to the first blind groove 23. The second liquid port 22 is communicated to the second blind groove 24. In the embodiment, both the first liquid port 21 and the second liquid port 22 are round blind holes extended inward from the top of the main body 20, both the first blind groove 23 and the second blind groove 24 are elongated-strip shaped blind grooves extended inward from the bottom of the main body 20, but the present disclosure is not limited to this embodiment. The shapes of the first liquid port 21, the second liquid port 22, the first blind groove 23, and the second blind groove 24 may be modified according to different needs.

The separating plate 30 is arranged between the bottom seat 10 and the main body 20, and the separating plate 30 covers the fin group 11 to form a heat exchange chamber 60 with the bottom seat 10. In detail, the separating plate 30 is a rectangular cover structure, that is the separating plate 30 is formed by a plate body and a surrounding wall surrounding an outer periphery of a bottom of the plate body to cover and shield the fin group 11. The separating plate 30 has a first convex block 31, a second convex block 32, a first through groove 33, and a second through groove 34. Both the first convex block 31 and the second convex block 32 are arranged on a top of the separating plate 30, and both the first through groove 33 and the second through groove 34 penetrate the separating plate 30 along an up-down direction of the separating plate 30 (penetrate the top and the bottom of the separating plate 30). The first convex block 31 fills a part of the first blind groove 23 such that the first convex block 31 and the first blind groove 23 together form a first channel 70. The second convex block 32 fills a part of the second blind groove 24 such that the second convex block 32 and the second blind groove 24 together form a second channel 80. The heat exchange chamber 60 is communicated to the first channel 70 through the first through groove 33, so as to be communicated to the first liquid port 21 through the first channel 70. The heat exchange chamber 60 is communicated to the second channel 80 through the second through groove 34, so as to be communicated to the second liquid port 22 through the second channel 80. In addition, the first liquid port 21 of the embodiment is substantially perpendicular to the first channel 70, and the second liquid port 22 is substantially perpendicular to the second channel 80, so as to reduce a pressure of the coolant when entering into or leaving from the main body 20.

In the embodiment, both the first sealing ring 40 and the second sealing ring 50 are made of a rubber material, but the present disclosure is not limited to this embodiment. The first sealing ring 40 is arranged between the bottom seat 10 and the main body 20, and the first sealing ring 40 surrounds a periphery of the separating plate 30. The second sealing ring 50 is arranged between the bottom seat 10 and the main body 20, and the second sealing ring 50 surrounds a periphery of the first sealing ring 40. Therefore, since the first sealing ring 40 is arranged between the bottom seat 10 and the main body 20 and surrounds the periphery of the separating plate 30, and the second sealing ring 50 is arranged between the bottom seat 10 and the main body 20 and surrounds the periphery of the first sealing ring 40, the first sealing ring 40 and the second sealing ring 50 may increase the sealing performance of the liquid cooling head. In addition, since the first convex block 31 of the separating plate 30 fills the part of the first blind groove 23 to form the first channel 70, and the second convex block 32 of the separating plate 30 fills the part of the second blind groove 24 to form the second channel 80, the first convex block 31 and the second convex block 32 may increase positioning effect between the components, so as to improve assembly convenience and overall structural strength.

Details are provided as follows. The bottom seat 10 has an indentation 12. The indentation 12 is located on the top of the bottom seat 10, and the fin group 11 is located in the indentation 12. In detail, the indentation 12 and the fin group 11 may be formed when the cooling fins 111 are skived or when casting, the present disclosure does not limit it. In the embodiment, the surrounding wall of the separating plate 30 is fixed to an inner wall of the indentation 12, such that a bottom surface of the indentation 12, the plate body of the separating plate 30, and the surrounding wall of the separating plate 30 together form the heat exchange chamber 60 to make the separating plate 30 position relative to the bottom seat 10, but the present disclosure is not limited to this embodiment.

In the embodiment, the first through groove 33 of the separating plate 30 is substantially perpendicular to each of the cooling fins 111, and the first through groove 33 is correspondingly located at a center of each of the cooling fins 111. Therefore, when the coolant enters the first through groove 33 from the cooling channels of the heat exchange chamber 60 or enters the cooling channels of the heat exchange chamber 60 from the first through groove 33, the coolant may flow evenly without causing obstruction or slowdown. In addition, the second through groove 34 is substantially parallel to each of the cooling fins 111, and the second through groove 34 is correspondingly located on a side of each of the cooling fins 111. Therefore, when the coolant enters the second through groove 34 from the cooling channels of the heat exchange chamber 60 or enters the cooling channels of the heat exchange chamber 60 from the second through groove 34, the coolant may flow evenly without causing obstruction or slowdown.

Details are provided as follows. The first convex block 31 and the second convex block 32 may be rectangle, circle, rhombus, polygon, irregular shape, elongated strip shape, L-shape, or other shapes not mentioned, the shape of the first convex block 31 and the second convex block 32 may be modified according to different needs. In the embodiment, the first convex block 31 is elongated strip shape, the second convex block 32 is L-shape, but the present disclosure is not limited to this embodiment. Therefore, the first convex block 31 and the second convex block 32 respectively fill the first blind groove 23 and the second blind groove 24 of the main body 20, such that the separating plate 30 may be initially positioned relative to the main body 20 without wobbling, and the initial positioning of the separating plate 30 and the main body 20 may improve the ease of assembly when the main body 20 is combined with the bottom seat 10.

In addition, the main body 20 further has an acceleration chamber 25. The first through groove 33 is communicated to the first channel 70 through the acceleration chamber 25. In detail, the main body 20 forms a through hole 26 on a bottom of the acceleration chamber 25 to make the acceleration chamber 25 be communicated to the first through groove 33 of the separating plate 30. In other words, the first liquid port 21 is sequentially communicated to the first channel 70, the acceleration chamber 25, the through hole 26, the first through groove 33, and the heat exchange chamber 60. The acceleration chamber 25 is used for mounting a driver (not shown in figures). The driver may be a pump or a fan, such that a suction force or a driving force generated by the driver during operation may force the coolant to flow within the liquid cooling head of the present disclosure. It shall be noted that a flow direction of the coolant may depend on whether the driver rotates in a forward or reverse direction, the present disclosure is therefore not limited to the coolant to enter the main body 20 from the first liquid port 21 or the second liquid port 22.

More specifically, when the first liquid port 21 serves as the inlet of the liquid cooling head of the present disclosure, the coolant flows through the first liquid port 21, the first channel 70, the acceleration chamber 25, the first through groove 33, the heat exchange chamber 60, the second through groove 34, the second channel 80, and the second liquid port 22 sequentially to finish the heat exchange to leave. When the second liquid port 22 serves as the inlet of the liquid cooling head of the present disclosure, the coolant flows through the second liquid port 22, the second channel 80, the second through groove 34, the heat exchange chamber 60, the first through groove 33, the acceleration chamber 25, the first channel 70, and the first liquid port 21 sequentially to finish the heat exchange and then exits.

Details are provided as follows. The main body 20 of the present disclosure further has a first annular groove 27 and a second annular groove 28 located on the bottom of the main body 20, but the present disclosure is not limited to this embodiment. The first annular groove 27 and the second annular groove 28 may also be located on the top of the bottom seat 10 or respectively located on the bottom of the main body 20 and the top of the bottom seat 10 in other embodiments. In detail, the first annular groove 27 correspondingly surrounds the periphery of the separating plate 30, and the second annular groove 28 correspondingly surrounds a periphery of the first annular groove 27. At least a part of the first sealing ring 40 is accommodated in the first annular groove 27, and the first sealing ring 40 is elastically abutted between the first annular groove 27 and the bottom seat 10. At least a part of the second sealing ring 50 is accommodated in the second annular groove 28, and the second sealing ring 50 is elastically abutted between the second annular groove 28 and the bottom seat 10. Therefore, the first sealing ring 40 may initially prevent the coolant leakage at the interfaces among the bottom seat 10, the main body 20, and the separating plate 30, and the second sealing ring 50 may serve as a second layer to ensure that the coolant may not leak to the outside.

In the liquid cooling head of the present disclosure, the first sealing ring 40 is arranged between the bottom seat 10 and the main body 20 and surrounds a periphery of the separating plate 30, the second sealing ring 50 is arranged between the bottom seat 10 and the main body 20 and surrounds a periphery of the first sealing ring 40, so as to efficiently increase sealing performance of the liquid cooling head. In addition, the first convex block 31 of the separating plate 30 fills the part of the first blind groove 23 to form the first channel 70, and the second convex block 32 of the separating plate 30 fills the part of the second blind groove 24 to form the second channel 80, so as to increase positioning effect between the components.

It shall be understood that the present disclosure may have other types of embodiments, and a person with ordinary skills in the art of the technical field of the present disclosure may make various changes and modifications corresponding to the present disclosure without deviating the principle and substance of the present disclosure; however, such corresponding changes and modification shall be considered to be within the claimed scope of the present disclosure.

What is claimed is:

1. A liquid cooling head, comprising:
a bottom seat, comprising a fin group;
a main body, arranged on the bottom seat correspondingly to the fin group, the main body comprising a first liquid port, a second liquid port, a first blind groove, and a second blind groove, the first liquid port communicated to the first blind groove, the second liquid port communicated to the second blind groove;
a separating plate, arranged between the bottom seat and the main body and covering the fin group to form a heat exchange chamber, the separating plate comprising a first convex block, a second convex block, a first through groove, and a second through groove, the first convex block filling a part of the first blind groove to form a first channel, the second convex block filling a part of the second blind groove to form a second channel, the heat exchange chamber communicated to the first channel through the first through groove, the heat exchange chamber communicated to the second channel through the second through groove;
a first sealing ring, arranged between the bottom seat and the main body and surrounding the separating plate; and
a second sealing, arranged between the bottom seat and the main body and surrounding the first sealing ring.

2. The liquid cooling head according to claim 1, wherein the fin group comprises a plurality of cooling fins, each of the cooling fins is parallel to each other, the first through groove is perpendicular to each of the cooling fins, the second through groove is parallel to each of the cooling fins.

3. The liquid cooling head according to claim 2, wherein the first through groove is correspondingly located at a center of each of the cooling fins, the second through groove is correspondingly located on a side of each of the cooling fins.

4. The liquid cooling head according to claim 1, wherein the first convex block is elongated strip shape or L-shape.

5. The liquid cooling head according to claim 1, wherein the main body further comprises an acceleration chamber, the first through groove is communicated to the first channel through the acceleration chamber.

6. The liquid cooling head according to claim 1, wherein the main body further comprises a first annular groove and a second annular groove, at least a part of the first sealing ring is accommodated in the first annular groove, at least a part of the second sealing ring is accommodated in the second annular groove.

7. The liquid cooling head according to claim 1, wherein the first liquid port is perpendicular to the first channel.

8. The liquid cooling head according to claim 1, wherein the second liquid port is perpendicular to the second channel.

9. The liquid cooling head according to claim 1, wherein the first liquid port and the second liquid port are located on same side of the main body.

10. The liquid cooling head according to claim 1, wherein the bottom seat comprises an indentation, the fin group is located in the indentation, the separating plate is fixed in the indentation.
